(19) United States
(12) Patent Application Publication
(10) Pub. No.: US 2020/0258735 A1
(43) Pub. Date: Aug. 13, 2020

(54) WAFER POLISHING METHOD AND APPARATUS

(71) Applicant: SUMCO CORPORATION, Tokyo (JP)

(72) Inventors: Takashi NISHITANI, Tokyo (JP); Ryuichi TANIMOTO, Tokyo (JP); Ryoya TERAKAWA, Tokyo (JP)

(73) Assignee: SUMCO CORPORATION, Tokyo (JP)

(21) Appl. No.: 15/774,470

(22) PCT Filed: Nov. 4, 2016
(86) PCT No.: PCT/JP2016/082762

§ 371 Date: May 8, 2018

(30) Foreign Application Priority Data
Nov. 13, 2015 (JP) 2015-223286

(51) Int. Cl. H01L 21/02; B24B 37/08

(52) U.S. Cl. CPC H01L 21/02024; B24B 37/08

(57) ABSTRACT

A wafer polishing method according to the present invention is provided with: a first polishing step (step S1) of polishing a wafer using a polishing head of an independent pressurizing system having a retainer ring capable of performing pressing operation independently of a wafer pressurizing mechanism; and a second polishing step (step S3) of polishing the wafer that has been polished in the first polishing step using a polishing head of a fixed pressurizing system having a retainer ring fixed to the wafer pressurizing mechanism.

### TECHNICAL FIELD

The present invention relates to a wafer polishing method and a wafer polishing apparatus and, more particularly to a wafer polishing method and a wafer polishing apparatus for multistage polishing process.

### BACKGROUND ART

Silicon wafers are widely used as a substrate material for semiconductor devices. Silicon wafers are manufactured by sequentially applying processes such as outer periphery grinding, slicing, lapping, etching, double-side polishing, single-side polishing, cleaning, etc., to a silicon single crystal ingot. Among the above processes, the single-side polishing process is a process required in order to remove unevenness or waviness of the wafer surface and thus to enhance flatness, in which mirror finishing by CMP (Chemical Mechanical Polishing) method is performed.

Typically, in the single-side polishing process for a silicon wafer, a single wafer polishing apparatus (CMP apparatus) is used. The wafer polishing apparatus includes a rotating platen to which a polishing cloth is affixed and a polishing head that holds a wafer on the rotating platen while pressing the wafer. The apparatus polishes one surface of the wafer by rotating the rotating platen and the polishing head while feeding slurry.

There is also known a wafer polishing apparatus that performs a multistage polishing process. For example, Patent Document 1 describes a semiconductor wafer polishing apparatus provided with a plurality of rotating platens, a plurality of polishing heads, and a plurality of load/unload stations and capable of performing multistage CMP process of a different number of stages. Further, Patent Document 2 describes a wafer polishing apparatus wherein three or more rotating platens are arranged rectilinearly, wafer holding heads are provided corresponding to the respective rotating platens, and transfer of the wafers between the wafer holding heads and a wafer conveying mechanism is made at positions corresponding to the respective rotating platens.

The type of the polishing head used in the wafer polishing apparatus mainly includes a fixed pressurizing system and an independent pressurizing system. A polishing head of the fixed pressurizing system has a configuration in which a retainer ring for restricting horizontal movement of the wafer is fixed to a wafer pressurizing mechanism, and a polishing head of the independent pressurizing system has a configuration in which the retainer ring is independent of the wafer pressurizing mechanism. A polishing head of a template type that applies cylinder pressurizing to the wafer through a back pad contacting the upper surface of the wafer employs the fixed pressurizing system, and a polishing head of a membrane type that applies air pressurizing to the wafer through a membrane contacting the upper surface of the wafer employs the independent pressurizing system.

In the polishing head of the independent pressurizing system, the membrane uniformly pressurizes the entire surface of the wafer, so that it is possible to suppress waviness of the wafer surface to thereby sufficiently enhance flatness; on the other hand, in this system, a vertical relative position between the wafer and the retainer ring is varied during polishing, so that where there is a gap between the retainer ring and the polishing cloth, the wafer may spin out through the gap. Therefore, in the independent pressurizing system, the retainer ring is pressed against the rotating platen, that is, the retainer ring is brought into contact with (grounded to) the polishing cloth to enhance a holding force for holding the wafer in the horizontal direction to thereby prevent spin-out of the wafer. On the other hand, in the polishing head of the fixed pressurizing system, the vertical relative position between the wafer and the retainer ring is not varied during polishing, so that it is possible to restrict the horizontal movement of the wafer without grounding the retainer ring to thereby prevent spin-out of the wafer.

### CITATION LIST

### Patent Document

[Patent Document 1] Japanese Patent Application Laid-Open No. 2007-335876

[Patent Document 2] Japanese Patent Application Laid-Open No. 2000-117627

### SUMMARY OF THE INVENTION

### Problem to be Solved by the Invention

Conventional wafer polishing apparatuses that perform a multistage polishing process are aimed to be used in the manufacturing process of a semiconductor device, so that although polishing conditions such as the type of slurry or polishing cloth or the polishing time may be made different between stages of the polishing process, the system of the polishing head is not changed for each stage. For example, the polishing head of the same system is used in both the front and rear stages of a two-stage wafer polishing process.

However, when the polishing head of the fixed pressurizing system is employed in each stage of the multistage polishing process, the shape of the polishing head or the shape of suction holes for holding the wafer formed in the back pad is transferred to the wafer, degrading the flatness of the wafer. On the other hand, when the polishing head of the independent pressurizing system is employed, the shape of the polishing head is not transferred to the wafer, but the quality of LPD (Light Point Defects), such as defects or particles on the wafer surface are degraded under the influence of retainer debris generated by wear of the retainer ring grounded to the polishing cloth.

The present invention has been made to solve the above problems, and the object thereof is to provide a wafer polishing method and a wafer polishing apparatus capable of enhancing the flatness and LPD quality of the wafer.

### Means for Solving the Problem

To solve the above problems, a wafer polishing method according to the invention includes a first polishing step of polishing a wafer using a polishing head of an independent pressurizing system having a retainer ring capable of performing pressing operation independently of a wafer pressurizing mechanism and a second polishing step of polishing the wafer that has been polished in the first polishing step using a polishing head of a fixed pressurizing system having a retainer ring fixed to the wafer pressurizing mechanism.

According to the present invention, a polishing process using the polishing head of the independent pressurizing system is first performed, and then finish polishing using the polishing head of the fixed pressurizing system is performed, so that it is possible to enhance LPD quality while ensuring high wafer flatness.

In the present invention, a polishing amount of the wafer in the second polishing step is preferably smaller than that in the first polishing step. Thus, it is possible to ensure LPD quality without degrading the flatness of the wafer.

The wafer polishing method according to the present invention preferably further includes a wafer transfer step of transferring the wafer that has been polished in the first polishing step from the polishing head of the independent pressurizing system to the polishing head of the fixed pressurizing system. In this case, the wafer transfer step preferably transfers the wafer through a movable stage capable of moving between a first transfer position at which the wafer can be transferred to the polishing head of the independent pressurizing system and a second transfer position at which the wafer can be transferred to the polishing head of the fixed pressurizing system. Using the movable stage in the wafer transfer step allows the wafer to be smoothly transferred between a plurality of polishing units using the polishing heads of different pressure systems. Thus, switching of the polishing head can be easily performed, whereby a high-quality wafer can efficiently be manufactured.

It is also preferable that the wafer transfer step transfers the wafer through a common stage fixedly disposed between the polishing head of the independent pressurizing system and the polishing head of the fixed pressurizing system. Using the common stage in the wafer transfer step allows the wafer to be transferred with a simpler configuration than that when the movable stage is used.

Further, a wafer polishing apparatus according to the present invention includes first and second polishing heads that press and hold a wafer on a rotating platen to which a polishing cloth is affixed and a wafer transfer mechanism that transfers a wafer that has been polished using the first polishing head from the first polishing head to the second polishing head, wherein the first polishing head is a polishing head of an independent pressurizing system including a first wafer pressurizing mechanism and a first retainer ring capable of performing pressing operation independently of the first wafer pressurizing mechanism, and the second polishing head is a polishing head of a fixed pressurizing system including a second wafer pressurizing mechanism and a second retainer ring fixed to the second wafer pressurizing mechanism.

When polishing is performed using the polishing head of the independent pressurizing system, flatness of the wafer can be ensured, but it is difficult to ensure LPD quality of the wafer. However, according to the present invention, finish polishing is performed using the polishing head of the fixed pressurizing system after the polishing using the polishing head of the independent pressurizing system, so that it is possible to enhance LPD quality while ensuring high flatness of the wafer.

In the wafer polishing apparatus according to the present invention, it is preferable that a plurality of polishing units are arranged in multiple stages and that the second polishing head constitutes a polishing unit of the final stage. Thus, when the polishing head of the fixed pressurizing system is provided in the polishing unit of the final stage, it is possible to manufacture a wafer having both high flatness and high LPD quality in the multiple stage configuration.

In the present invention, it is preferable that the wafer transfer mechanism has a movable stage capable of moving between a first transfer position at which the wafer can be transferred to the first polishing head and a second transfer position at which the wafer can be transferred to the second polishing head and that the movable stage transfers the wafer transferred thereto from the first polishing head at the first transfer position to the second transfer position so as to transfer the wafer to the second polishing head. Using the movable stage as the wafer transfer mechanism allows the wafer to be smoothly transferred between a plurality of polishing units using the polishing heads of different pressure systems. Thus, switching of the polishing head can be easily performed, whereby a high-quality wafer can efficiently be manufactured.

In the present invention, it is also preferable that the wafer transfer mechanism includes a common stage fixedly disposed between the first and second polishing heads and that the wafer that has been polished by the first polishing head is transferred from the first polishing head to the second polishing head through the common stage. Using the common stage as the wafer transfer mechanism allows the wafer transfer mechanism to be realized with a simpler configuration than that when the movable stage is used.

### Advantageous Effects of the Invention

According to the present invention, it is possible to provide a wafer polishing method and apparatus capable of enhancing both flatness and LPD quality of the wafer.

### BRIEF DESCRIPTION OF DRAWINGS

FIG. 1 is a schematic plan view illustrating a configuration of a wafer polishing apparatus according to a first embodiment of the present invention;

FIGS. 2A and 2B are schematic cross-sectional views illustrating the configurations of the polishing heads, specifically FIG. 2A illustrates a polishing head of the independent pressurizing system, and FIG. 2B illustrates a polishing head of the fixed pressurizing system;

FIG. 3 is a flowchart for explaining a wafer polishing process using the wafer polishing apparatus 1;

FIG. 4 is a schematic plan view illustrating a configuration of a wafer polishing apparatus according to a second embodiment of the present invention.

### DETAILED DESCRIPTION OF THE EMBODIMENTS

Preferred embodiments of the present invention will be described in detail below with reference to the accompanying drawings.

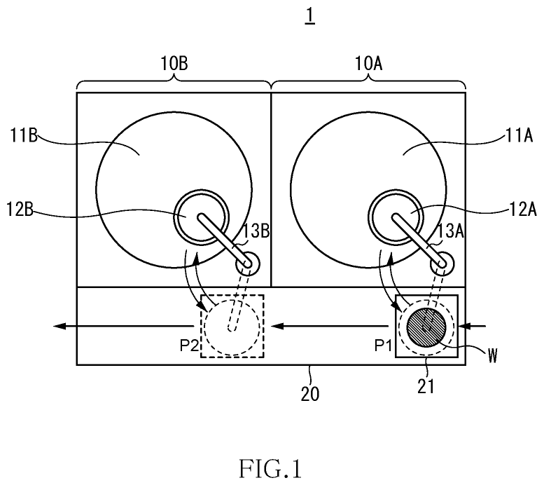

FIG. 1 is a schematic plan view illustrating a configuration of a wafer polishing apparatus according to a first embodiment of the present invention.

As illustrated in FIG. 1, a wafer polishing apparatus 1 includes first and second polishing units 10A and 10B arranged in series in the order of processes and a wafer transfer mechanism 20 that transfers a wafer that has been polished in the first polishing unit 10A to the second polishing unit 10B. The wafer transfer mechanism 20 has a movable stage 21, and the wafer is transferred between the first and second polishing units 10A and 10B through the movable stage 21. FIG. 1 illustrates a state where a wafer W is placed on the movable stage 21.

The first and second polishing units 10A and 10B are each a single wafer CMP apparatus and have rotating platens 11A and 11B, respectively, each attached with a polishing cloth and polishing heads 12A and 12B, respectively, that hold the wafer on the rotating platens 11A and 11B. The polishing head 12A (first polishing head) which is a polishing head of an independent pressurizing system (membrane type) is mounted in the first polishing unit 10A and is configured to be movable by an arm 13A. The polishing head 12B (second polishing head) which is a polishing head of a fixed pressurizing system (template type) is mounted in the second polishing unit 10B and is configured to be movable by an arm 13B.

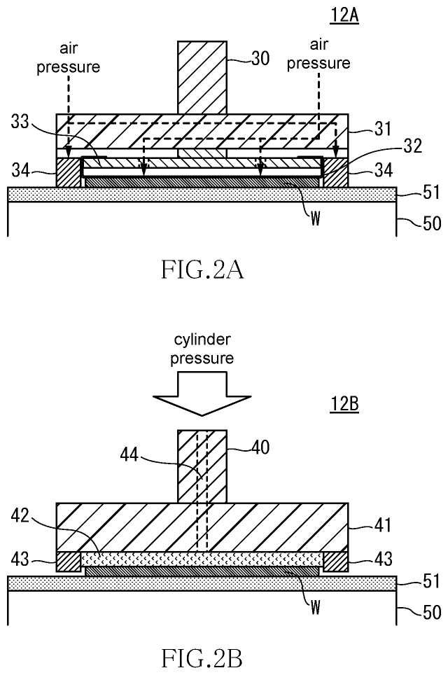

FIGS. 2A and 2B are schematic cross-sectional views illustrating the configurations of the polishing heads 12A and 12B, respectively. FIG. 2A illustrates the polishing head 12A of the independent pressurizing system, and FIG. 2B illustrates the polishing head 12B of the fixed pressurizing system.

As illustrated in FIG. 2A, the polishing head 12A of the independent pressurizing system includes a rigid base 31 (head body), made of metal or ceramic, connected to the lower end of a rotary shaft 30, a membrane 32 with a single-chamber structure provided below the base 31 so as to contact the upper surface of the wafer W, a support plate 33 that supports the membrane 32, and a retainer ring 34 provided on the outer peripheral side of the membrane 32 so as to surround the outer periphery of the wafer W. The membrane 32 is brought into contact with the upper surface of the wafer W in a state of being inflated by air pressure to thereby press the wafer W against a polishing cloth 51 on the rotating platen 50.

The retainer ring 34 is a member made of resin or ceramic and has a role of limiting the movable range of the wafer W in the horizontal direction by abutting against the outer peripheral end surface of the wafer W. The retainer ring 34 is capable of performing pressing operation independently of the membrane 32 constituting a wafer pressurizing mechanism and is pressed against the rotating platen 50 by air pressure different from that for the membrane 32 to be brought into contact with the polishing cloth 51. That is, the retainer ring 34 is pressure-controlled by air pressure from an air supply source difference from that for the membrane 32. This can enhance the force of limiting the movable range of the wafer W by the retainer ring 34, thereby making it possible to prevent the wafer W from spinning out of the polishing head 12A during polishing.

As illustrated in FIG. 2B, the polishing head 12B of the fixed pressurizing system includes a rigid base 41 (head body), made of metal or ceramic, connected to the lower end of a rotary shaft 40, a back pad (vacuum suction plate) 42 provided below the base 41, and a retainer ring 43 provided on the bottom surface side of the base 41 and outer peripheral side of the back pad 42 so as to contact the outer peripheral end surface of the wafer W and has a structure in which a vacuum channel 44 communicates with suction holes of the back pad 42. In this fixed pressurizing system, the entire polishing head 12B is pressed down by cylinder pressure to press the base 41 against the upper surface of the wafer W through the back pad 42, whereby the wafer W is pressed against the polishing cloth 51 on the rotating platen 50.

The retainer ring 43 is a fixed member fixed to the outer peripheral portion of the bottom surface of the base 41 and is raised and lowered together with the rotary shaft 40, base 41 and back pad 42 driven to be raised or lowered by a pressure cylinder. That is, the retainer ring 43 is fixed to the base 41 constituting a wafer pressurizing mechanism and cannot be moved up and down independently of the wafer pressurizing mechanism.

In the polishing head 12A of the independent pressurizing system, the membrane 32 uniformly pressurizes the entire surface of the wafer W, so that the wafer W can be polished evenly to thereby enhance the flatness of the wafer W; however, the retainer ring 34 always contacts the polishing cloth, so that the LPD quality of the wafer W is degraded under the influence of retainer debris generated by wear of the retainer ring 34. On the other hand, in the polishing head 12B of the fixed pressurizing system, the retainer ring 43 does not contact the polishing cloth 51, so that resin waste or the like is not generated from the retainer ring 43, thus making it possible to sufficiently enhance the LPD quality of the wafer W; however, the shape of the polishing head 12A or the shape of suction holes for holding the wafer formed in the back pad is transferred to the wafer W, making it difficult to sufficiently enhance the flatness of the wafer w.

However, by adopting the polishing head of the independent pressurizing system at the front stage of the two-stage wafer polishing process as in the present embodiment, it is possible to scrape wafer W while ensuring a sufficient degree of flatness. Further, by adopting the polishing head of the fixed pressurizing system at the rear stage of the two-stage wafer polishing process, it is possible to enhance the LPD quality while preventing a reduction in the flatness of the wafer W. That is, by performing finish polishing using the polishing head 12B of the fixed pressurizing system, it is possible to recover or improve the LPD quality of the wafer W reduced by the polishing using the polishing head 12A of the independent pressurizing system.

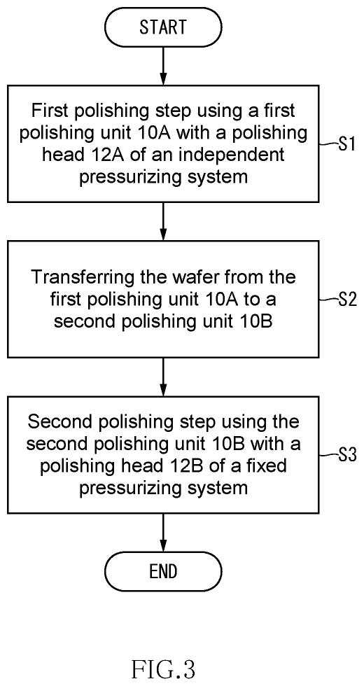

FIG. 3 is a flowchart for explaining a wafer polishing process using the wafer polishing apparatus 1.

As illustrated in FIG. 3, in the wafer polishing process, a first polishing step is performed first using the first polishing unit 10A (step S1). The wafer W to be polished is, e.g., a bulk silicon wafer sliced from a silicon single crystal ingot, in particular, whose flatness has been enhanced by double-sided polishing.

As illustrated in FIG. 1, the wafer W transferred from a loader (not illustrated) to the movable stage 21 is carried to the front (first transfer position P1) of the first rotating platen 11A by the movable stage 21. The wafer W on the movable stage 21 is picked up (chucked) by the polishing head 12A and then set on the first rotating platen 11A. Then, the wafer is polished while being held by the polishing head 12A of the independent pressurizing system. The polishing amount (machining allowance) of the wafer at this time is, e.g., 200 nm to 1000 nm.

In the first polishing step, it is required not only to remove damage on the wafer surface and reduce roughness of the wafer surface, but also to maintain the wafer shape (flatness) obtained by the double-side polishing. Since the polishing head 12A of the independent pressurizing system provides a higher shape maintaining performance than that of the polishing head 12B of the fixed pressurizing system, the polishing head 12A of the independent pressurizing system is used in the first polishing step.

After completion of the first polishing step by the first polishing unit 10A, the wafer transfer mechanism 20 transfers the wafer W from the first polishing unit 10A to the second polishing unit 10B (step S2). The wafer W on the first rotating platen 11A is picked up by the polishing head 12A and is released (dechucked) on the movable stage 21. Thereafter, the wafer W is conveyed to the front (second transfer position P2) of the second rotating platen 11B by the movable stage 21.

Then, a second polishing step by the second polishing unit 10B is performed (step S3). After the wafer W on the movable stage 21 is picked up by the polishing head 12B and set on the second rotating platen 11B. Then, the wafer is finish-polished while being held by the polishing head 12B of the fixed pressurizing system. The polishing amount (machining allowance) of the wafer at this time is smaller than that in the first polishing step and is, e.g., 5 nm to 50 nm.

In the second polishing step, removal of micro-damage introduced in the first polishing step is required. A generation source of the micro-damage is retainer debris generated by wear of the retainer ring 34 grounded to the polishing cloth 51. By switching the polishing head of the independent pressurizing system to that of the fixed pressurizing system for finish polishing, it is possible to remove the micro-damage while suppressing additional generation thereof to thereby reduce the haze level and LPD.

After completion of the second polishing step by the second polishing unit 10B, the wafer W on the second rotating platen 11B is picked up by the polishing head 12B and is released on the movable stage 21. Then, the wafer W is conveyed to a predetermined position by the movable stage 21 and transferred to an unloader and, thus, a series of wafer polishing processes is completed.

As described above, in the wafer polishing method according to the present embodiment, the polishing head 12A of the independent pressurizing system (membrane type) is employed in the first polishing step to realize the flatness of the wafer, and the polishing head 12B of the fixed pressurizing system (template type) is employed in the second polishing step to ensure the LPD quality of the wafer surface, so that it is possible to increase both the flatness and LPD quality of the wafer. Further, the movable stage 21 is used as the wafer transfer mechanism 20 for the switching of the polishing head, so that wafer transfer between a plurality of polishing units using polishing heads with different polishing systems (pressure systems) can be smoothly performed, whereby it is possible to efficiently manufacture a high-quality wafer.

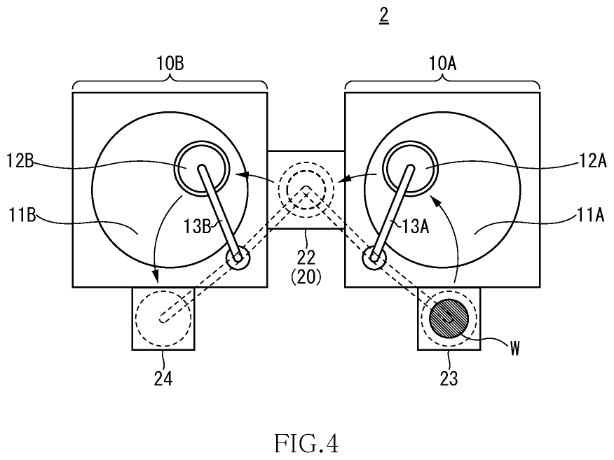

FIG. 4 is a schematic plan view illustrating a configuration of a wafer polishing apparatus according to a second embodiment of the present invention.

As illustrated in FIG. 4, in a wafer polishing apparatus 2 of the present embodiment, the first and second polishing heads 12A and 12B serve as the wafer transfer mechanism and a common stage 22 is used. The common stage 22 as a wafer transfer place is provided between the first and second polishing units 10A and 10B. The common stage 22 constitutes apart of the wafer transfer mechanism and is fixedly arranged between the first and second polishing heads 12A and 12B.

The wafer W picked up by the polishing head 12A from a loader 23 disposed in front of the first polishing unit 10A is set on the first rotating platen 11A. Then, the first polishing step (step S1 in FIG. 3) is performed in a state where the wafer W is held by the polishing head 12A of the independent pressurizing system.

After completion of the first polishing step by the first polishing unit 10A, the wafer W is transferred from the first polishing unit 10A to the second polishing unit 10B (step S2). The wafer W on the first rotating platen 11A is transferred onto the common stage 22 by the polishing head 12A, and then the polishing head 123 of the second polishing unit 10B chucks the wafer W on the common stage 22 and transfers the wafer W onto the second rotating platen 11B of the second polishing unit 10B. The wafer picked up by the polishing head 12B is set at a polishing start position on the second rotating platen 11B. Then, the second polishing step (step S3 in FIG. 3) is performed in a state where the wafer is held by the polishing head 12B of the fixed pressurizing system.

In the second polishing step S3, the polishing amount of the wafer is smaller than that in the first polishing step and is 5 nm to 50 nm. The larger the polishing amount becomes, the larger the effect of the polishing head of the fixed pressurizing system is, with the result that the flatness of the wafer is degraded, so that it is better for the polishing amount to be as small as possible as long as the LPD quality can be ensured.

The polishing conditions in the second polishing step may be the same as or different from those in the first polishing step. For example, the type of slurry used in the second polishing step is not particularly limited and may be the same as or different from that used in the first polishing step.

After completion of the second wafer polishing step by the second polishing unit 10B, the wafer on the second rotating platen 11B is picked up by the polishing head and transferred onto an unloader 24, whereby a series of wafer polishing processes is completed.

As described above, the wafer polishing apparatus 2 according to the present embodiment uses the common stage 22 as the wafer transfer mechanism 20 for the switching of the polishing head, so that, in addition to the effect of the invention obtained in the first embodiment, the wafer transfer mechanism 20 can be realized with a very simple configuration.

While the preferred embodiments of the present invention have been explained above, the present invention is not limited thereto and may be variously modified without departing from the scope of the present invention.

Accordingly, all such modifications are included in the present invention.

For example, in the above embodiments, the wafer polishing apparatus has a configuration in which the two polishing units are arranged in series; however, the number of the polishing units may be three or more in the present invention. However, in this case, the polishing head of the polishing unit of the final stage needs to be the fixed pressurizing system, and at least one of the polishing units other than that of the final stage is the polishing head of the independent pressurizing system. Thus, when two or more polishing units are arranged in series, the second polishing unit constitutes a polishing unit of the final stage, so that polishing conditions such as the type of slurry may be different for each polishing unit or the same among all the polishing units.

Further, the wafer to be polished in the present invention is not limited to a bulk wafer sliced from a single crystal silicon ingot, but wafers of various materials may be used.

### REFERENCE SIGNS LIST

1, 2 wafer polishing apparatus
10A, 10B polishing unit
11A, 11B rotating platen
12A, 12B polishing head
13A, 13B arm
20 wafer transfer mechanism
21 movable stage
22 common stage
23 loader
24 unloader
30 rotary shaft
31 base (polishing head body)
32 membrane
33 support plate
34 retainer ring
40 rotary shaft
41 base
42 back pad
43 retainer ring
44 vacuum channel
50 rotating platen
51 polishing cloth
W wafer

1. A wafer polishing method comprising:
a first polishing step of polishing a wafer using a polishing head of an independent pressurizing system having a retainer ring capable of performing pressing operation independently of a wafer pressurizing mechanism; and
a second polishing step of polishing the wafer that has been polished in the first polishing step using a polishing head of a fixed pressurizing system having a retainer ring fixed to the wafer pressurizing mechanism.

2. The wafer polishing method as claimed in claim 1, wherein a polishing amount of the wafer in the second polishing step is smaller than that in the first polishing step.

3. The wafer polishing method as claimed in claim 1 further comprising a wafer transfer step of transferring the wafer that has been polished in the first polishing step from the polishing head of the independent pressurizing system to the polishing head of the fixed pressurizing system.

4. The wafer polishing method as claimed in claim 3, wherein the wafer transfer step transfers the wafer through a movable stage capable of moving between a first transfer position at which the wafer can be transferred to the polishing head of the independent pressurizing system and a second transfer position at which the wafer can be transferred to the polishing head of the fixed pressurizing system.

5. The wafer polishing method as claimed in claim 3, wherein the wafer transfer step transfers the wafer through a common stage fixedly disposed between the polishing head of the independent pressurizing system and the polishing head of the fixed pressurizing system.

6. A wafer polishing apparatus comprising:
first and second polishing heads that press and hold a wafer on a rotating platen to which a polishing cloth is affixed; and
a wafer transfer mechanism that transfers a wafer that has been polished using the first polishing head from the first polishing head to the second polishing head,
wherein the first polishing head is a polishing head of an independent pressurizing system including a first wafer pressurizing mechanism and a first retainer ring capable of performing pressing operation independently of the first wafer pressurizing mechanism, and
the second polishing head is a polishing head of a fixed pressurizing system including a second wafer pressurizing mechanism and a second retainer ring fixed to the second wafer pressurizing mechanism.

7. The wafer polishing apparatus as claimed in claim 6, wherein a plurality of polishing units are arranged in multiple stages and the second polishing head constitutes a polishing unit of the final stage.

8. The wafer polishing apparatus as claimed in claim 6, wherein
the wafer transfer mechanism has a movable stage capable of moving between a first transfer position at which the wafer can be transferred to the first polishing head and a second transfer position at which the wafer can be transferred to the second polishing head, and
the movable stage transfers the wafer transferred thereto from the first polishing head at the first transfer position to the second transfer position so as to transfer the wafer to the second polishing head.

9. The wafer polishing apparatus as claimed in claim 6, wherein
the wafer transfer mechanism includes a common stage fixedly disposed between the first and second polishing heads, and
the wafer that has been polished by the first polishing head is transferred from the first polishing head to the second polishing head through the common stage.

10. The wafer polishing method as claimed in claim 2 further comprising a wafer transfer step of transferring the wafer that has been polished in the first polishing step from the polishing head of the independent pressurizing system to the polishing head of the fixed pressurizing system.

11. The wafer polishing method as claimed in claim 10, wherein the wafer transfer step transfers the wafer through a movable stage capable of moving between a first transfer position at which the wafer can be transferred to the polishing head of the independent pressurizing system and a second transfer position at which the wafer can be transferred to the polishing head of the fixed pressurizing system.

12. The wafer polishing method as claimed in claim 10, wherein the wafer transfer step transfers the wafer through a common stage fixedly disposed between the polishing head of the independent pressurizing system and the polishing head of the fixed pressurizing system.

13. The wafer polishing apparatus as claimed in claim 7, wherein
the wafer transfer mechanism has a movable stage capable of moving between a first transfer position at which the wafer can be transferred to the first polishing head and a second transfer position at which the wafer can be transferred to the second polishing head, and
the movable stage transfers the wafer transferred thereto from the first polishing head at the first transfer position to the second transfer position so as to transfer the wafer to the second polishing head.

14. The wafer polishing apparatus as claimed in claim 7, wherein
the wafer transfer mechanism includes a common stage fixedly disposed between the first and second polishing heads, and
the wafer that has been polished by the first polishing head is transferred from the first polishing head to the second polishing head through the common stage.
